(19) United States
(12) Patent Application Publication
(10) Pub. No.: US 2019/0096939 A1
(43) Pub. Date: Mar. 28, 2019

(54) Image Sensor, Color Filter Array, and Preparation Method Thereof

(71) Applicant: Huaian Imaging Device Manufacturer Corporation, Huaian (CN)

(72) Inventors: Ming WU, Huaian (CN); Hsiao-Che WU, Huaian (CN); Tsung-Hsien LIN, Huaian (CN); Long Chiang WU, Huaian (CN); Chao XUE, Huaian (CN); Xiao-Tong ZHU, Huaian (CN)

(21) Appl. No.: 16/107,974

(22) Filed: Aug. 21, 2018

(30) Foreign Application Priority Data
Sep. 26, 2017 (CN) 201710883039.6

(51) Int. Cl. H01L 27/146; G02B 5/20; H04N 5/378; G03F 7/00

(52) U.S. Cl. CPC H01L 27/14621; H01L 27/14627; G03F 7/0007; G02B 5/201; H04N 5/378; H01L 27/14612

(57) ABSTRACT

The present disclosure provides an image sensor, a color filter array, and a preparation method thereof. The method includes: etching a photosensitive array substrate to form a plurality of strip-shaped first color filters, arranged at intervals in a first direction, a width direction thereof being parallel to the first direction; and etching the photosensitive array substrate to form block-shaped second and third color filters, the second and third color filters being disposed within the intervals of the first color filters and distributed in a second direction alternately, wherein the first direction is perpendicular to the second direction. An RGB arrangement manner different from a traditional manner is proposed from the perspective of layout design, thereby breaking a single RGB layout arrangement manner and providing more space for RGB design.

### CROSS REFERENCES

This application claims the benefit of priority to Chinese Patent Application No. CN201710883039.6, entitled “Image Sensor, Color Filter Array, and Preparation Method thereof”, filed with SIPO on Sep. 26, 2017, the contents of which are incorporated herein by reference in its entirety.

### TECHNICAL FIELD

The present application relates to the technical field of semiconductors devices, and more specifically, relates to an image sensor, a color filter array, and a preparation method thereof.

### BACKGROUND

CCD or CMOS image sensors are core components of a digital imaging system. A charge coupled device or CCD is an electronic light sensor. A CMOS image sensor is an image sensor fabricated on CMOS technology. Both these sensors detect incident light and convert the incident light into electrical signals by photo detect or elements, one of the mainly differences between a CCD and a CMOS image sensor is the method used to read out the signal. In addition to a photodiode, CCD further includes a storage unit for controlling adjacent charges. The effective photosensitive area in a CCD photosensitive element is relatively large, a strong optical signal may be received, and correspondingly an electrical signal output has a higher signal to noise comparing with a CMOS sensor under the same conditions. The CMOS photosensitive unit is more complicated than that of CCD. In addition to a photo detect or at the front, an active pixel CMOS sensor includes an amplifier and an analog-to-digital conversion circuit. Each imaging element comprises a photodiode and multiple electronic components, the photodiode being a small part of the element.

Each photosensitive element makes to an image unit in the image sensor. Since the photosensitive element can only sense the intensity of light but cannot capture color information, a color CCD/CMOS image sensor needs a color filter in front of the photosensitive element. Different sensor manufacturers have different solutions. The most common method is to cover red/green/blue (RGB) filters and to form a color pixel with four image elements in a ratio of 1:2:1 (i.e., the red and blue filters cover one image point separately, and the remaining two image pixels are covered by the green filter). The reason for this ratio is that human eyes are more sensitive to green. As shown in FIG. 1, a color pixel 1 includes four image pixels, a red filter R and a blue filter B cover two image pixels on a diagonal line, and two image pixels on the remaining diagonal line are separately covered by a green filter G.

After receiving light, the photosensitive element generates an electric current, and the current related to the light intensity, so an electrical signal directly outputs by the photosensitive element is an analog signal. In the CCD sensor, this charge is directly output to a storage unit of the next photosensitive element instead of being further processed by each element, then is combined with an analog signal generated by the element and then output to the third photosensitive element. Analogously, the signal of the last photosensitive element is combined to form a unified output. Since the electrical signals generated by the photosensitive elements are too weak to directly perform analog-to-digital conversion, such output data must be subjected to unified amplification processing. This task is performed by the amplifier in the CCD sensor specially. After being processed by the amplifier, the electrical signal intensity of each image pixel is increased by the same amplitude. However, since the CCD itself cannot directly convert the analog signal to a digital signal, a dedicated analog-to-digital conversion chip is also required for processing, and eventually the signal is output to a dedicated DSP processing chip in a form of a binary digital image matrix. Each photosensitive element in the CMOS sensor directly integrates an amplifier and analog-to-digital conversion logic. After the photosensitive diode receives light and generates an analog electrical signal, the electrical signal is first amplified by the amplifier in the photosensitive element, and then directly converted into a corresponding digital signal.

In a traditional process of making an image sensor, when preparing a filter, green light material in a green region is not connected (on diagonal lines, respectively), so control requirements for the process are very high.

Therefore, there is an urgent need in reducing the demanding process steps for the preparation of a filter.

### SUMMARY

The present application provides an image sensor, a color filter array, and a preparation method.

The present application provides a color filter array, comprising: a plurality of first color filters in strip-shapes, a plurality of second color filters in block-shapes, and a plurality of third color filters in block-shapes; wherein the strip of each of the plurality of first color filters are arranged in parallel in a first direction spaced by an interval from each other, a width of each strip is parallel to the first direction; wherein the plurality of second color filters and the plurality of third color filters are disposed alternately along a second direction inside the intervals between adjacent two of the first color filters and, wherein the first direction is perpendicular to the second direction.

Preferably, the pluralities of first color filters, the second color filters, and the third color filters are green filters, red filters and blue filters, respectively.

Preferably, the second color filters are aligned in the first direction, and the third color filters are aligned in the first direction.

Preferably, the second color filters and the third color filters are arranged alternately in the first direction.

Preferably, each of the first color filters, the second color filters, and the third color filters has a same dimension in the second direction, the second color filters and the third color filters have a same dimension in the first direction.

Preferably, the color filter array further comprises a metal grid wherein the metal grid forms a border of each of the first, the second and third color filters wherein the metal grid blocks and reduces crosstalk among the first, the second and third color filters.

The present application further provides an image sensor, comprising:

a microlens array disposed on the color filter array and configured to focus incident light to the color filter array, wherein color filter array filter the focused incident light into a plurality of monochromatic light; and a photosensitive array substrate disposed under the color filter array, receiving and converting the plurality of monochromatic light into electrical signals.

Preferably, the photosensitive array substrate further comprises a layer formed of photosensitive devices, a metal interconnection layer, and a dielectric layer; wherein the photosensitive devices capable of converting optical signals to electrical signals; wherein the metal interconnection layer is disposed under the photosensitive device layer and configured for outputting the electrical signals of the photosensitive devices, and wherein the dielectric layer is disposed between the metal interconnection layer and the interconnect layer.

Preferably, the photosensitive devices comprise a photosensitive element for photoelectric conversion and a transistor for reading out an electrical signal.

The present application further provides a preparation method for a color filter array, comprising: forming a first color filter material layer on a photosensitive array substrate, and patterning the first color filter material layer to form a plurality of strip-shaped first color filters and intervals between two adjacent strip-shaped first color filters arranged in a first direction, and each of the strips has a width in the first direction; forming a second color filter material layer on the photosensitive array substrate and the first color filter, and patterning the second color filter material layer to form block-shaped second color filters inside the intervals of the first color filters, wherein the second color filters are aligned in the first direction; and forming a third color filter material layer on the photosensitive array substrate, the first color filter and the second color filter, and patterning the third color filter material layer to form block-shaped third color filters in the intervals of the first color filters, wherein the third color filters and the second color filters, are arranged to alternating in a first direction and wherein the first direction is perpendicular to the second direction.

The present application further provides a preparation method for a color filter array, the preparation method for a color filter array comprising:

forming a first color filter material layer on a photosensitive array substrate, and patterning the first color filter material layer to form a plurality of strip-shaped first color filters and intervals between two adjacent strip-shaped first color filters arranged in a first direction, and each of the strips has a width in the first direction;

forming a second color filter material layer on the photosensitive array substrate and the first color filter, and patterning the second color filter material layer to form block-shaped second color filters inside the intervals of the first color filters, wherein the second color filters are aligned in the first direction; and forming a third color filter material layer on the photosensitive array substrate, the first color filter and the second color filter, and patterning the third color filter material layer to form block-shaped third color filters in the intervals of the first color filters, wherein the third color filters and the second color filters, are arranged to alternating in a first direction and wherein the first direction is perpendicular to the second direction.

More preferably, patterning the first color filter material layer and the second color filter material layer comprises: coating the first color filter material layer and the second color filter material layer with photoresists, selectively exposing a pattern of the blocks, developing resist, and then dry-etching or wet-etching a color filter material layer to be removed.

Preferably, the third color filter material layer is dry-etched or wet-etched to expose the first color filters and the second color filters, and the third color filters are formed within intervals of the first color filters and upper layers of the second color filters.

Preferably, before forming the first color filter material layer on the photosensitive array substrate, further comprises a step of forming a metal grid on the photosensitive array substrate.

As described above, the image sensor, the color filter array, and the preparation method therefor according to the present application have the following beneficial effects: according to the image sensor, the color filter array and the preparation method thereof according to the present application, a green filter is coated, exposed and developed jointly, so as to be conducive to improvement of a filter preparation process and simplification of press conditions. An RGB arrangement manner different from a traditional manner is proposed from the perspective of layout design, thereby breaking a single RGB layout arrangement manner and providing more space for RGB design.

### BRIEF DESCRIPTION OF THE DRAWINGS

FIG. 1 shows a top-view structure diagram of a conventional color pixel.

FIG. 2 shows a top-view structure diagram of a color filter array according to an embodiment of the present disclosure.

FIG. 3 shows a top-view structure diagram of an implementation manner of a color filter array according another embodiment of the present disclosure.

FIG. 4, which is a cross section of FIG. 2, shows a side-view structure diagram of an image sensor according to an embodiment of the present disclosure.

FIG. 5 shows a side-view structure diagram of forming a first color filter material layer on a photosensitive array substrate according to another embodiment of in the present disclosure.

FIG. 6 shows a side-view structure diagram of forming a first color filter by etching according to another embodiment of the present disclosure.

FIG. 7 shows a top-view structure diagram of forming a first color filter by etching according another embodiment of the present disclosure.

FIG. 8 shows a side-view structure diagram of forming a second color filter material layer on a photosensitive array substrate and a first color filter according another embodiment of the present disclosure.

FIG. 9 shows a side-view structure diagram of forming a second color filter by etching according another embodiment of the present disclosure.

FIG. 10 shows a top-view structure diagram of an embodiment of forming a second color filter by etching according to another embodiment of the present disclosure.

FIG. 11 shows a side-view structure diagram of forming a third color filter material layer on a photosensitive array substrate, a first color filter, and a second color filter according to another embodiment of the present disclosure.

FIG. 12 shows a side-view structure diagram of forming a third color filter by etching according to another embodiment of the present disclosure.

FIG. 13 shows a top-view structure diagram of forming a third color filter by etching according to another embodiment of the present disclosure.

FIG. 14 shows a side-view structure diagram of forming a second color filter by etching according to another embodiment of the present disclosure.

FIG. 15 shows a top-view structure diagram of forming a second color filter by etching according to another embodiment of the present disclosure.

FIG. 16 shows a side-view structure diagram of forming a third color filter material layer on a photosensitive array substrate, a first color filter, and a second color filter according to another embodiment of the present disclosure.

FIG. 17 shows a top-view structure diagram of forming a third color filter by etching according to another embodiment of the present disclosure.

### DESCRIPTION OF COMPONENT REFERENCE NUMERALS

1 Color pixel
2 Color filter array
21 First color filter
21a First color filter material layer
22 Second color filter
22a Second color filter material layer
23 Third color filter
23a Third color filter material layer
3 Photosensitive array substrate
4 Oxide layer
5 Microlens array
S11-S13 Steps
S21-S23 Steps

### DETAILED DESCRIPTION OF THE PREFERRED EMBODIMENTS

The embodiments of the present disclosure will be described below with reference to specific examples. Those skilled in the art may easily understand other advantages and effects of the present disclosure by the contents disclosed in the present specification. The present disclosure may also be implemented or applied through other different specific embodiments. Various modifications or changes may also be made on the details in the present specification without departing from the spirit of the present disclosure based on different view pixels and disclosures.

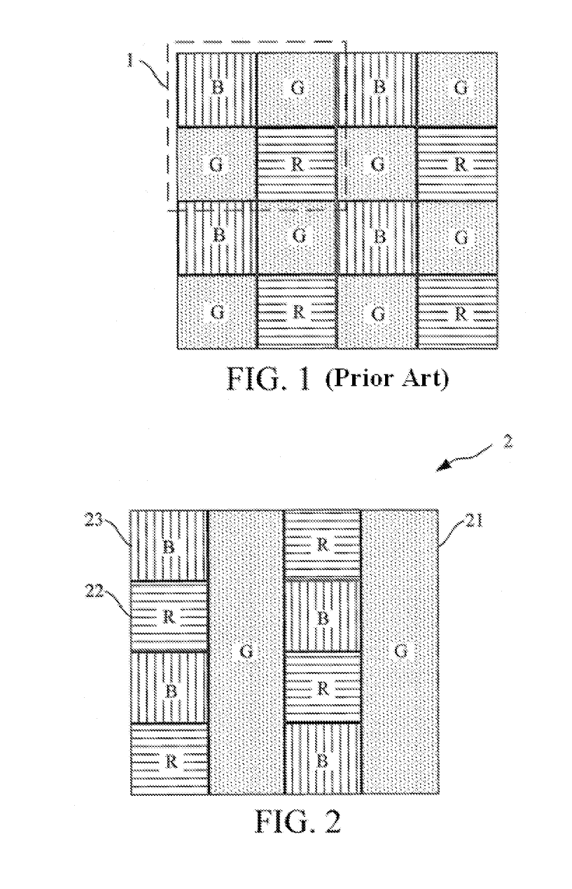

Please refer to FIG. 2 to FIG. 17. It should be noted that the illustration provided in the present embodiment merely illustrates the basic concept of the present disclosure by way of illustration. Although only components related to the present disclosure are shown in the illustration, they are not drawn according to the number, shape, and size of the components in actual implementation. The form, quantity, and proportion of various components in actual implementation may be a random change, and the layout of the components may also be more complex.

### Embodiment 1

As shown in FIG. 2, the present embodiment provides a color filter array 2, the color filter array 2 comprises:

first color filters 21 in strip-shape, second color filters 22 in block-shape, third color filters 23 in block-shape, and a metal grid (not shown in the figure). The first color filters 21, the second color filters 22 and the third color filters 23 are green filters, red filters and blue filters, respectively. In the present embodiment, the first color filters 21 are green filters, the second color filters 22 are red filters, and the third color filters 23 are blue filters. Other color filter combinations are also applicable to the present disclosure, and are not limited to be the three colors listed in the present embodiment.

As shown in FIG. 2, the first color filters 21 are of a strip-shaped structure, the plurality of first color filters 21 are arranged at intervals along a first direction, and a width direction of each first color filter 21 is parallel to the first direction.

Specifically, in the present embodiment, the first direction is an X-axis direction. The first color filters 21 are laid in parallel into a Y-axis direction, and all the first color filters 21 are distributed at intervals in the X-axis direction.

As shown in FIG. 2, the second color filters 22 have a block-shaped structure, and are disposed in the intervals between two first color filters 21.

Specifically, the second color filters 22 are in staggered distribution in the X-axis direction. As shown in FIG. 2, in the present embodiment, the second color filters 22 are distributed at second and fourth (even) positions on a first column of filters, a second column of filters is a green filter 21 of entire piece, and the second color filters 22 are distributed at first and third (odd) positions on a third column of filters.

As shown in FIG. 2, the third color filters 23 are of a block-shaped structure, and disposed within the intervals of the first color filters 21, the third color filters 23 and the second color filters 22 are distributed in a second direction alternately, and the second direction is perpendicular to the first direction.

Specifically, in the present embodiment, the second direction is a Y-axis direction. The third color filters 23 and the second color filters 22 are distributed in the Y-axis direction alternately, and the third color filters 23 are in staggered distribution in the X-axis direction. As shown in FIG. 2, in the present embodiment, the third color filters 23 are distributed at first and third (odd) positions on a first column of filters, a second column of filters is a green filter 21 of entire piece, and the third color filters 23 are distributed at second and fourth (even) positions on a third column of filters.

As shown in FIG. 2, a color pixel is taken as an example. The present embodiment comprises two types of color pixels, each color pixel comprises four image pixels, wherein, in the first color pixel, the blue filter 23 covers the upper left image pixel, the red filter 22 covers the lower left image pixel, and the green filters 21 cover the two right image pixels; in the second color pixel, the blue filter 23 covers the lower left image pixel, the red filter 22 covers the upper left image pixel, and the green filters 21 cover the two right image pixels. The first color pixels and the second color pixels are distributed in the X-axis direction alternately, and the same column of pixels adopts color pixels of the same type.

As shown in FIG. 2, in the present embodiment, the second color filter 22 and the third color filter 23 is of a square structure, and the width of the first color filter 21 is the same as the side length of the second color filter 22 and the third color filter 23.

The metal grid (not shown in the figure) is disposed between the color filters, and configured to isolate two adjacent color filters, thereby avoiding crosstalk.

### Embodiment 2

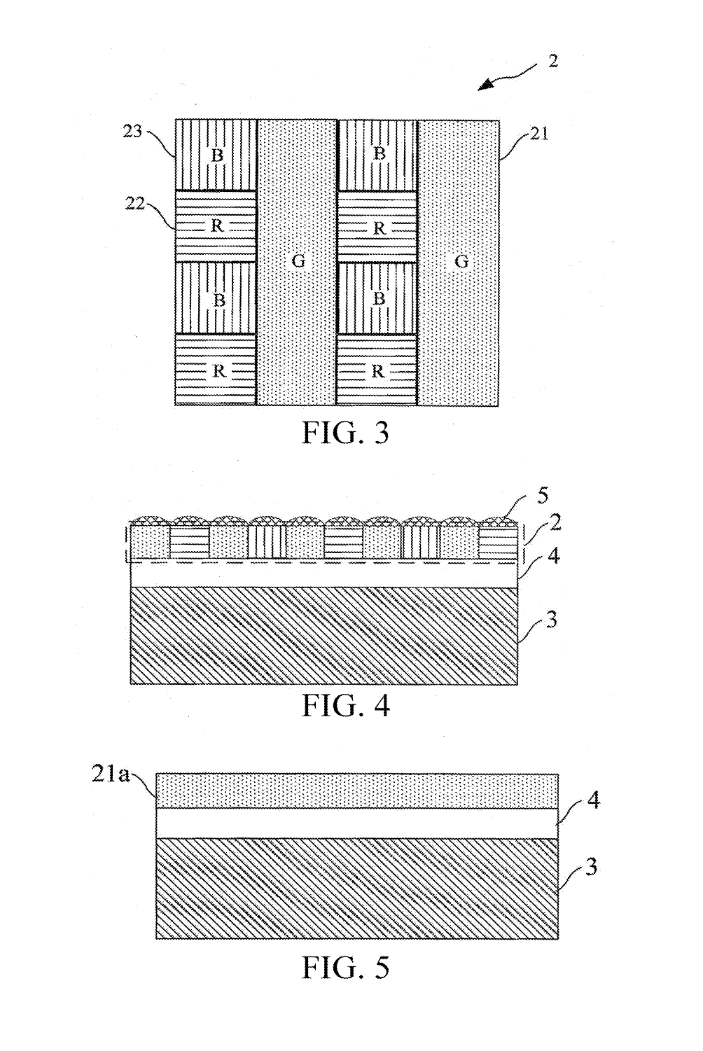

As shown in FIG. 3, the present embodiment provides a color filter array 2, the color filter array 2 at least comprises:

first color filters 21 in strip-shape, second color filters 22 in block-shape, third color filters 23 in block-shape, and a metal grid. The first color filters 21, the second color filters 22 and the third color filters 23 are green filters, red filters and blue filters, respectively. In the present embodiment, the first color filters 21 are green filters, the second color filters 22 are red filters, and the third color filters 23 are blue filters.

As shown in FIG. 3, the first color filters 21 are of a strip-shaped structure, the plurality of first color filters 21 are arranged at intervals in a first direction, and a width direction of each first color filter 22 is parallel to the first direction.

Specifically, in the present embodiment, the first direction is an X-axis direction. The first color filters 21 are laid in parallel in a Y-axis direction, and all the first color filters 21 are distributed at intervals in the X-axis direction.

As shown in FIG. 3, the second color filters 22 are of a block-shaped structure, and disposed within the intervals of the first color filters 21.

Specifically, the second color filters 22 are in aligned distribution in the X-axis direction. As shown in FIG. 3, in the present embodiment, the second color filters 22 are distributed at second and fourth (even) positions on a first column of filters, a second column of filters is a green filter 21 of entire piece, and the second color filters 22 are distributed at second and fourth (even) positions on a third column of filters.

As shown in FIG. 3, the third color filters 23 are of a block-shaped structure, and disposed within the intervals of the first color filters 21, the third color filters and the second color filters 22 are distributed in a second direction alternately, and the second direction is perpendicular to the first direction.

Specifically, in the present embodiment, the second direction is a Y-axis direction. The third color filters 23 and the second color filters 22 are distributed in the Y-axis direction alternately, and the third color filters 23 are in aligned distribution in the X-axis direction. As shown in FIG. 2, in the present embodiment, the third color filters 23 are distributed at first and third (odd) positions on a first column of filters, a second column of filters is an entire piece of green filter 21, and the third color filters 23 are distributed at first and third (odd) positions on a third column of filters.

As shown in FIG. 3, a color pixel is taken as an example. The present embodiment comprises a color pixel, the color pixel comprising four image pixels, wherein, in the first color pixel the blue filter 23 covers the upper left image pixel, the red filter 22 covers the lower left image pixel, and the green filters 21 cover the two right image pixels. The color pixels are arranged in an array in the X-axis direction and the Y-axis direction.

In the present embodiment, the structure and function of the metal grid are the same as those in Embodiment 1, which will not be repeated here.

### Embodiment 3

As shown in FIG. 4 which is a cross section of FIG. 2, the present embodiment provides an image sensor, comprising: a photosensitive array substrate 3, an oxide layer 4, the color filter array 2, and a microlens array 5.

As shown in FIG. 4, the photosensitive array substrate 3 receives an optical signal, and converts the optical signal to an electrical signal.

Specifically, as an implementation embodiment of the present disclosure, the photosensitive array substrate 3 has a front side illumination structure, and comprises a photosensitive device layer, a metal interconnection layer, and a dielectric layer. The photosensitive device layer comprises a photosensitive element and a transistor, wherein the photosensitive element converts an optical signal to an electrical signal, and the photosensitive element comprises, but is not limited to, an optical gate, a PN type photodiode, or a PIN type photodiode; and the transistor is connected to the photosensitive element and used as a switch or an amplifying device for reading out the electrical signal. The metal interconnection layer is disposed on the photosensitive device layer and configured for electrical connection of devices in the photosensitive device layer. The dielectric layer is disposed on the metal interconnection layer and configured for insulation protection.

Specifically, as an implementation embodiment of the present disclosure, the photosensitive array substrate 3 has a backside illumination structure, and comprises a photosensitive device layer, a metal interconnection layer, and a dielectric layer. The metal interconnection layer is configured for electrical connection devices in the photosensitive device layer. The photosensitive device layer is disposed on the metal interconnection layer, and comprises a photosensitive element and a transistor, wherein the photosensitive element converts an optical signal to an electrical signal, and the photosensitive element comprises, but is not limited to, an optical gate, a PN type photodiode, or a PIN type photodiode; and the transistor is connected to the photosensitive element and used as a switch or an amplifying device for reading out the electrical signal. The dielectric layer is disposed on the photosensitive device layer and configured for insulation protection.

As shown in FIG. 4, the oxide layer 4 is disposed on the photosensitive array substrate 3 and configured for further insulation protection, and the oxide layer 4 may be set or removed as required.

As shown in FIG. 4, the color filter array 2 is disposed on the oxide layer 4 which is on the photosensitive array substrate 3, and configured to filter incident light into monochromatic colors.

Specifically, the structure of the color filter array 2 may be the structure in Embodiment 1 or the structure in Embodiment 2. In the present embodiment, the structure in Embodiment 1 is adopted, which will not be repeated here.

As shown in FIG. 4 which is a cross section of FIG. 2, the microlens array 5 is disposed on the color filter array 2, and configured to converge the incident light.

Specifically, the microlens array 5 converges the incident light and then transmits the converged incident light to the photosensitive element, so that the absorption efficiency of light can be improved.

### Embodiment 4

As shown in FIG. 5 to FIG. 13, the present disclosure provides a preparation method for a color filter array, comprising the following steps:

Step S11: form a first color filter material layer 21a on a photosensitive array substrate 3, and etch the first color filter material layer 21a to form a plurality of strip-shaped first color filters 21 arranged at intervals in a first direction, a width direction of each first color filter 21 is parallel to the first direction.

Specifically, in the present embodiment, in order to avoid crosstalk, a metal layer is first formed on the photosensitive array substrate 3 and etched to form a metal grid, the metal grid is located above an isolation region of each photosensitive element. Since the first color filter 21 has a strip-shaped structure, an etching process of the metal grid may be simplified, which will not be repeated here.

Specifically, as shown in FIG. 5, in the present embodiment, an oxide layer 4 is further formed on the photosensitive array substrate 3, the metal grid (not shown in the figure) is formed on the oxide layer 4, and the first color filter material layer 21a is coated on the oxide layer 4 and filled in grooves formed by the metal grid.

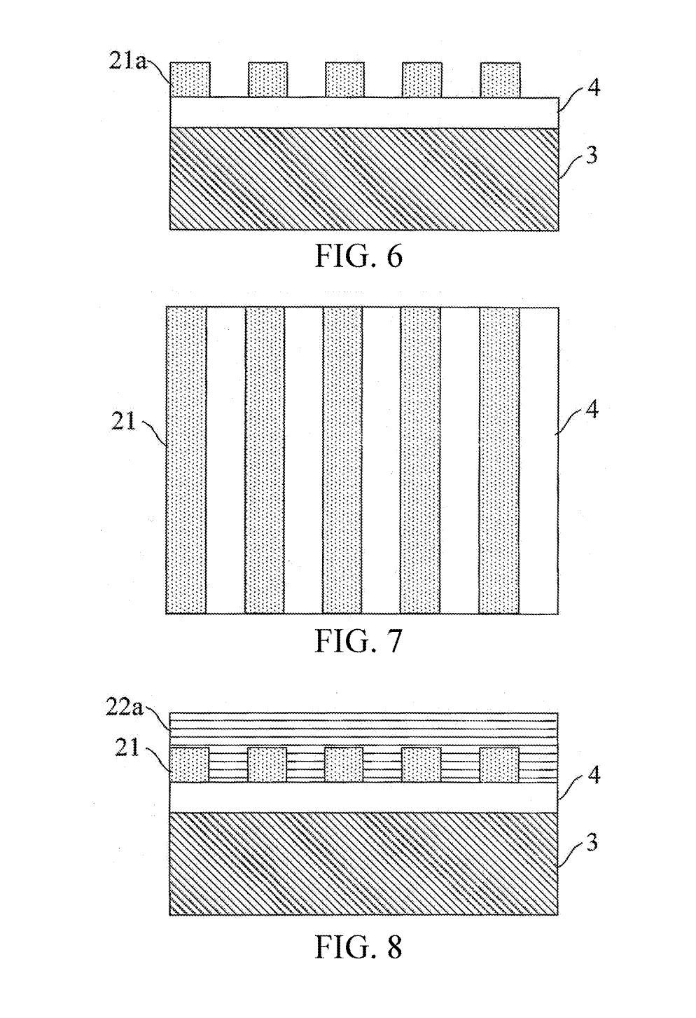

Specifically, as shown in FIG. 6 and FIG. 7, the first color filter material layer 21a is coated with photoresist; the photoresist is cured by pre-baking; and a portion to be etched away is exposed by a mask based on selective exposure. In the present embodiment, the portion to be etched away has a spaced strip-shaped structure; the photoresist is developed, so that a mask pattern is transferred to the photoresist; the photoresist is hardened by a hardener; and the exposed first color filter material layer 21a to be removed is etched away by dry-etching or wet-etching. In the present embodiment, wet etching is adopted, the operation is simple, the requirement for equipment is low, it is easy to realize mass production, and the etching selectivity is also good; and the photoresist is removed to form the first color filter 21.

Specifically, in the present embodiment, the first direction is an X-axis direction, and a second direction is a Y-axis direction.

Step S12: form a second color filter material layer 22a on the oxide layer 4 (photosensitive array substrate 3) and the first color filter 21, and etch the second color filter material layer 22a to form block-shaped second color filters 22 within the intervals of the first color filters 21, the second color filters 22 being distributed at intervals in the second direction and in staggered distribution in the first direction.

Specifically, as shown in FIG. 8, the second color filter material layer 22a is spin coated, and second color filter materials are formed on the surfaces of the first color filters 21 and within the intervals of the first color filters 21 (the first color filter material within a metal grid is etched away).

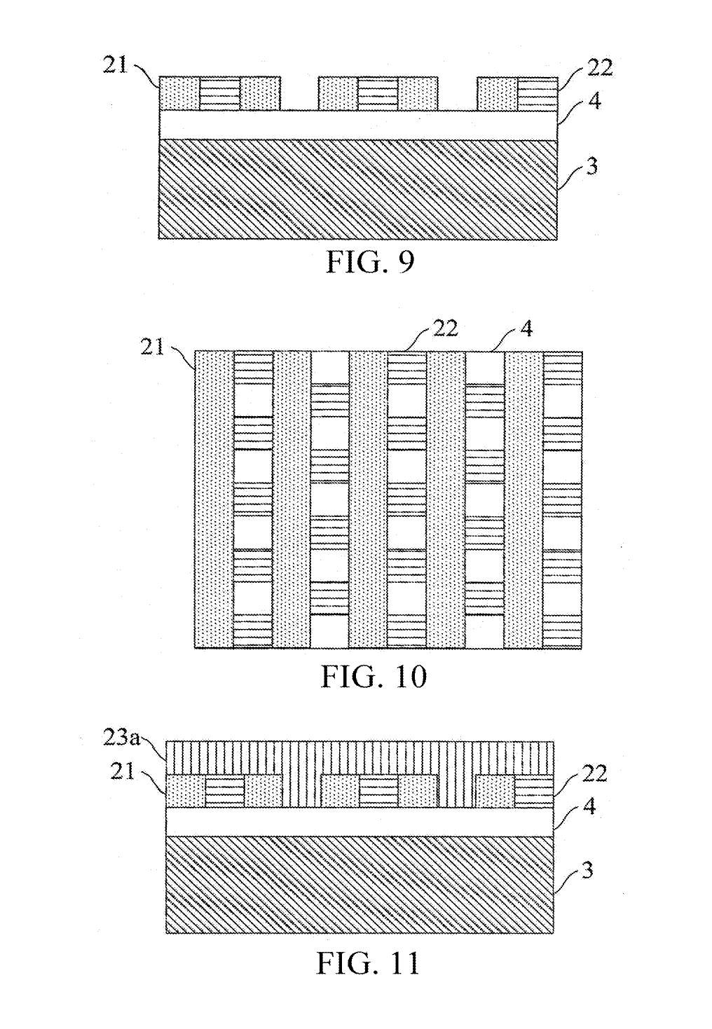

Specifically, as shown in FIG. 9 and FIG. 10, the second color filter material layer 22a is coated with a photoresist; the photoresist is cured by pre-baking; and a portion to be etched away is exposed by a mask based on selective exposure. In the present embodiment, the portion to be etched away is alternate portions in regions of the first color filters 21 and interval regions of the first color filters 21; the photoresist is developed, so a mask pattern is transferred to the photoresist; the photoresist is hardened by a hardener; and the exposed second color filter material layer 22a to be removed is etched away by dry-etching or wet-etching. In the present embodiment, wet etching is adopted, so the operation is simple, the requirement for equipment is low, it is easy to realize mass production, and the etching selectivity is also good; and the photoresist is removed to form the second color filter 22. In the present embodiment, the second color filters 22 are distributed in the X-axis direction alternately.

Step S13: form a third color filter material layer 23a on the oxide layer 4 (photosensitive array substrate 3), the first color filter 21, and the second color filter 22, etch the third color filter material layer 23a to form block-shaped third color filters 23 within the intervals of the first color filters 21 and the second color filters 22, and expose the first color filters 21 and the second color filters 22, the third color filters 23 are distributed at intervals in the second direction and in staggered distribution in the first direction.

Specifically, as shown in FIG. 11, the third color filter material layer 23a is spin coated, and third color filter materials are formed on the surfaces of the first color filters 21 and the surfaces of the second color filters 22, and within the intervals of the first color filters 21 (within a metal grid away which a second color filter material is etched).

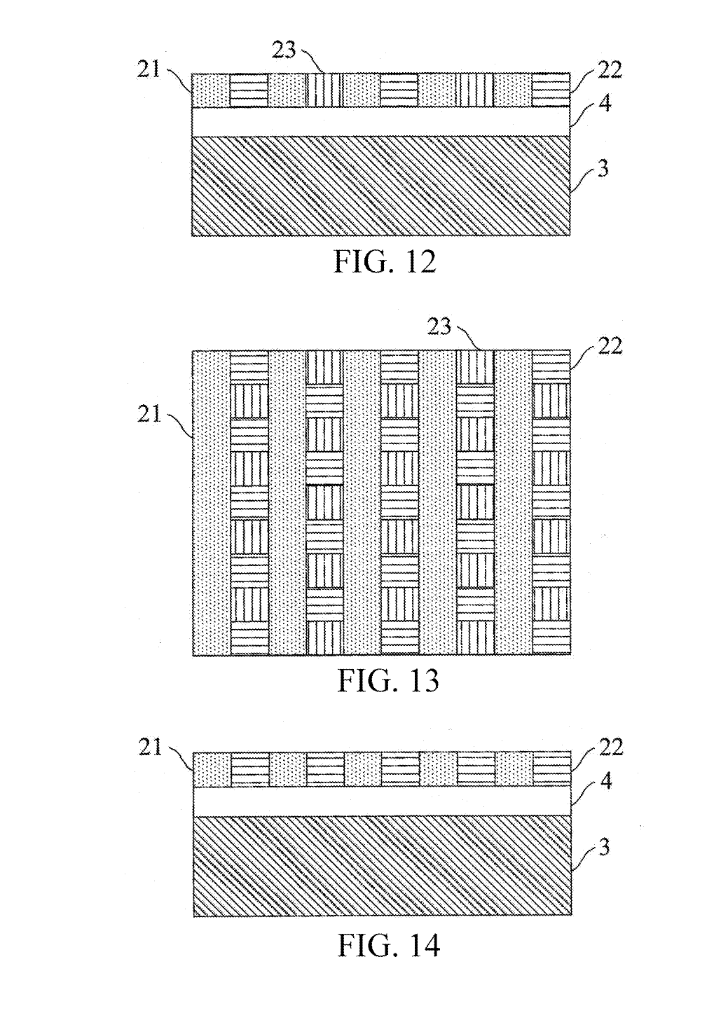

Specifically, as shown in FIG. 12 and FIG. 13, the third color filter material layer 23a is dry-etched or wet-etched to expose the first color filters 21 and the second color filters 22, and the third color filters 23 are formed within intervals of the first color filters 21 and the second color filters 22.

### Embodiment 5

As shown in FIG. 5 to FIG. 8 and FIG. 14 to FIG. 17, the present disclosure provides a preparation method for a color filter array, comprising the following steps:

Step S21: form a first color filter material layer 21a on a photosensitive array substrate 3, and etch the first color filter material layer 21a to form a plurality of strip-shaped first color filters 21 arranged at intervals in a first direction, a width direction of each first color filter 21 is parallel to the first direction.

Specific steps are the same as those in step S11 in Embodiment 4, which will not be repeated here, referring to FIG. 5 to FIG. 7. In the present embodiment, the first direction is an X-axis direction, and a second direction is a Y-axis direction.

Step S22: form a second color filter material layer 22a on an oxide layer 4 (photosensitive array substrate 3) and the first color filter 21, and etch the second color filter material layer 22a to form block-shaped second color filters 22 within the intervals of the first color filters 21, the second color filters 22 are distributed at intervals in the second direction and in aligned distribution in the first direction.

Specifically, as shown in FIG. 8, the second color filter material layer 22a is spin coated, and second color filter materials are formed on the surfaces of the first color filters 21 and within the intervals of the first color filters 21.

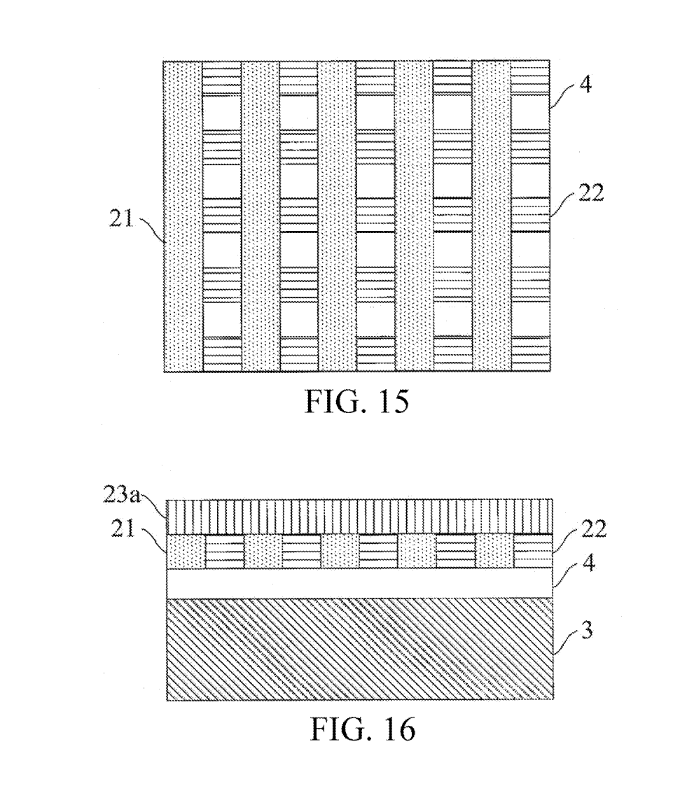

Specifically, as shown in FIG. 14 and FIG. 15, the second color filter material layer 22a is coated with photoresist; the photoresist is cured by pre-baking; and a portion to be etched away is exposed by a mask based on selective exposure. In the present embodiment, the portion to be etched away is alternate portions in regions of the first color filters 21 and interval regions of the first color filters 21; the photoresist is developed, so a mask pattern is transferred to the photoresist; the photoresist is hardened by a hardener; and the exposed second color filter material layer 22a to be removed is etched away by dry etching or wet etching. In the present embodiment, wet etching is adopted, so the operation is simple, the requirement for equipment is low, it is easy to realize mass production, and the etching selectivity is also good; and the photoresist is removed to form the second color filter 22. In the present embodiment, the second color filters 22 are in aligned distribution in the X-axis direction.

Step S23: form a third color filter material layer 23a on the oxide layer 4 (photosensitive array substrate 3), the first color filter 21 and the second color filter 22, and etch the third color filter material layer 23a to form block-shaped third color filters 23 within the intervals of the first color filters 21 and the second color filters 22, the third color filters 23 are distributed at intervals in a second direction and in aligned distribution in the first direction.

Specifically, as shown in FIG. 16, the third color filter material layer 23a is spin coated, and third color filter materials are formed on the surfaces of the first color filters 21 and the surfaces of the second color filters 22, and within the intervals of the first color filters 21.

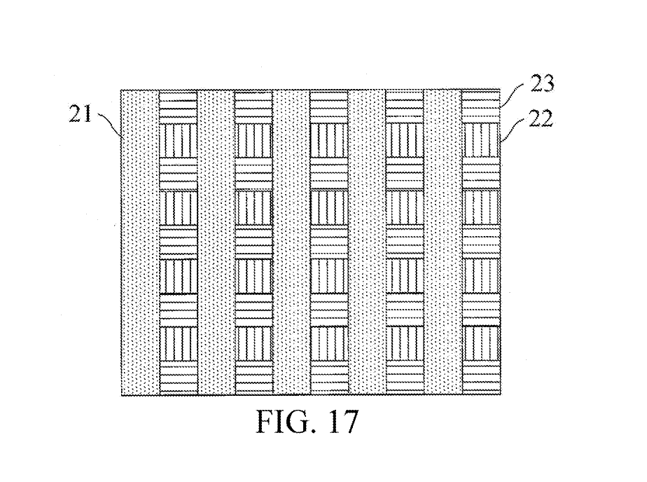

Specifically, as shown in FIG. 17, the third color filter material layer 23a is dry-etched or wet-etched to expose the first color filters 21 and the second color filters 22, and the third color filters 23 are formed within intervals of the first color filters 21 and the second color filters 22.

According to the image sensor, the color filter array and the preparation method therefor according to the present disclosure, a green filter is coated, exposed and developed jointly, so as to be conducive to improvement of a filter preparation process and simplification of process conditions. An RGB arrangement manner different from a traditional manner is proposed from the perspective of layout design, thereby breaking a single RGB layout arrangement manner and providing more space for RGB design.

To sum up, the present application provides an image sensor, a color filter array, and a preparation method thereof. The method comprises: etching a photosensitive array substrate to form a plurality of strip-shaped first color filters, arranged at intervals in a first direction, a width direction of first color filter being parallel to the first direction; and etching the photosensitive array substrate to form block-shaped second color filters, and etching the photosensitive array substrate to form block-shaped third color filters, the second color filters and the third color filters being disposed within the intervals of the first color filters and distributed in a second direction alternately, wherein the first direction is perpendicular to the second direction. A photosensitive array substrate, the foregoing color filter array, and a microlens array form an image sensor. According to the image sensor, the color filter array, and the preparation method thereof according to the present disclosure, a green filter is coated, exposed and developed jointly, so as to be conducive to improvement of a filter preparation process and simplification of process conditions. An RGB arrangement manner different from a traditional manner is proposed from the perspective of layout design, thereby breaking a single RGB layout arrangement manner and providing more space for RGB design. Therefore, the present disclosure effectively overcomes various disadvantages in the prior art and has a high industrial utilization value.

The above embodiments merely illustrate the principle and effects of the present disclosure, but are not to limit the present disclosure. Any person skilled in the art can modify or vary the above embodiments without departing from the spirit and scope of the present disclosure. Accordingly, all equivalent modifications or variations completed by those with ordinary skill in the art without departing from the spirit and technical thought disclosed in the present disclosure should still be covered by the claims of the present disclosure.

What is claimed is:

1. A color filter array, comprising:
a plurality of first color filters in strip-shapes, a plurality of second color filters in block-shapes, and a plurality of third color filters in block-shapes;
wherein the strips of each of the plurality of first color filters are arranged in parallel in a first direction spaced by an interval from each other, a width of each strip is parallel to the first direction;
wherein the plurality of second color filters and the plurality of third color filters are disposed alternately along a second direction inside the intervals between adjacent two of the first color filters and,
wherein the first direction is perpendicular to the second direction.

2. The color filter array according to claim 1, wherein the pluralities of first color filters, the second color filters, and the third color filters are green filters, red filters and blue filters, respectively.

3. The color filter array according to claim 1, wherein the second color filters are aligned in the first direction, and the third color filters are aligned in the first direction.

4. The color filter array according to claim 1, wherein the second color filters and the third color filters are arranged alternately in the first direction.

5. The color filter array according to claim 1, wherein each of the first color filters, the second color filters, and the third color filters has a same dimension in the second direction, the second color filters and the third color filters have a same dimension in the first direction.

6. The color filter array according to claim 1, further comprising a metal grid wherein the metal grid forms a border of each of the first, the second and third color filters wherein the metal grid blocks and reduces crosstalk among the first, the second and third color filters.

7. An image sensor, comprising the color filter array according to claim 1, further comprising:
a microlens array disposed on the color filter array and configured to focus incident light to the color filter array, wherein color filter array filter the focused incident light into a plurality of monochromatic light; and
a photosensitive array substrate disposed under the color filter array, receiving and converting the plurality of monochromatic light into electrical signals.

8. The image sensor according to claim 7, wherein the photosensitive array substrate further comprises a layer formed of photosensitive devices, a metal interconnection layer, and a dielectric layer; wherein the photosensitive devices capable of converting optical signals to electrical signals; wherein the metal interconnection layer is disposed under the photosensitive device layer and configured for outputting the electrical signals of the photosensitive devices, and wherein the dielectric layer is disposed between the metal interconnection layer and the interconnect layer.

9. The image sensor according to claim 7, wherein the photosensitive array substrate further comprises a layer formed of photosensitive devices, a metal interconnection layer, and a dielectric layer; wherein the metal interconnection layer is configured to connect to the photosensitive devices, and wherein the dielectric layer is disposed between the photosensitive device layer and the interconnect layer.

10. The image sensor according to claim 7, wherein the photosensitive devices comprise a photosensitive element for photoelectric conversion and a transistor for reading out an electrical signal.

11. A method for preparation a color filter array, comprising:
forming a first color filter material layer on a photosensitive array substrate;
patterning the first color filter material layer to form a plurality of strip-shaped first color filters and intervals between two adjacent strip-shaped first color filters, wherein the strips are pointing to a first direction, and each of the strips has a width in the first direction;
forming a second color filter material layer on the photosensitive array substrate and the first color filter, and patterning the second color filter material layer to form block-shaped second color filters in the intervals of the first color filters, wherein the second color filters are aligned in the first direction; and
forming a third color filter material layer on the photosensitive array substrate, the first color filters and the second color filters;
patterning the third color filter material layer to form block-shaped third color filters in the intervals of the first color filters;
wherein the third color filters and the second color filters are arranged alternately in the intervals in the first direction; and
wherein the first direction is perpendicular to the second direction.

12. A method for preparation a color filter array, comprising:
forming a first color filter material layer on a photosensitive array substrate, and patterning the first color filter material layer to form a plurality of strip-shaped first color filters and intervals between two adjacent strip-shaped first color filters arranged in a first direction, and each of the strips has a width in the first direction;
forming a second color filter material layer on the photosensitive array substrate and the first color filter, and patterning the second color filter material layer to form block-shaped second color filters inside the intervals of the first color filters, wherein the second color filters are aligned in the first direction; and
forming a third color filter material layer on the photosensitive array substrate, the first color filter and the second color filter, and patterning the third color filter material layer to form block-shaped third color filters in the intervals of the first color filters, wherein the third color filters and the second color filters, are arranged to alternating in a first direction and
wherein the first direction is perpendicular to the second direction.

13. The preparation method for a color filter array according to claim 11, wherein patterning the first color filter material layer and the second color filter material layer comprises: coating the first color filter material layer and the second color filter material layer with photoresists, selectively exposing a pattern of the blocks, developing resist, and then dry-etching or wet-etching a color filter material layer to be removed.

14. The preparation method for a color filter array according to claim 11, wherein the third color filter material layer is dry-etched or wet-etched to expose the first color filters and the second color filters, and the third color filters are formed within intervals of the first color filters and upper layers of the second color filters.

15. The preparation method for a color filter array according to claim 11, wherein before forming the first color filter material layer on the photosensitive array substrate, further comprises a step of forming a metal grid on the photosensitive array substrate.

16. The color filter array according to claim 2, wherein the second color filters are aligned in the first direction, and the third color filters are aligned in the first direction.

17. The color filter array according to claim 2, wherein the second color filters and the third color filters alternate in the first direction.

18. The color filter array according to claim 2, wherein each of the first color filters, each of the second color filters, and each of the third color filters has a same dimension in the first direction, wherein each of the second color filters and each of the third color filters has a same dimension in the first direction.

19. The image sensor according to claim 8, wherein the photosensitive devices each comprises a photosensitive element for photoelectric conversion and a transistor for reading out an electrical signal.

20. The image sensor according to claim 9, wherein the photosensitive devices each comprises a photosensitive element for photoelectric conversion and a transistor for reading out an electrical signal.
